(19) United States
(12) Patent Application Publication
(10) Pub. No.: US 2007/0138507 A1
(43) Pub. Date: Jun. 21, 2007

(54) Method of fabricating reduced subthreshold leakage current submicron NFET's with high III/V ratio material

(76) Inventors: Elizabeth C. Glass, Gilbert, AZ (US); Olin L. Hartin, Phoenix, AZ (US); Haldane S. Henry, Scottsdale, AZ (US); Philippe O. Jamet, Saint Ismier (FR); Lisa Z. Zhang, Gilbert, AZ (US); Michael W. Pelczynski, Phoenix, AZ (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/303,776

(22) Filed: Dec. 16, 2005

(51) Int. Cl. H01L 29/739

(52) U.S. Cl. 257/194; 438/590

(57) ABSTRACT

A method of fabricating an enhancement mode semiconductor device comprises providing a compound semiconductor substrate, epitaxially growing on the substrate a first portion of a buffer, the first portion including gallium arsenide (GaAs), growing a second portion of the buffer, the second portion including a high V/III ratio and high aluminum (Al) mole fraction aluminum gallium arsenide (AlGaAs), and epitaxially growing a stack of compound semiconductor layers on the buffer. An enhancement mode semiconductor device is then formed in the stack.

### BACKGROUND

The present disclosures relate to heterostructure field effect transistors, and more particularly, to a reduced subthreshold leakage current submicron NFET and a method of fabricating the same with high III/V ratio material.

In current radio frequency (RF) products and technologies, market pressure is to reduce wireless subscriber unit power amplifier module cost while improving performance. This requires the use of shorter gate length devices. Some of the smallest field effect transistors (FETs) are heterostructure FETs (HFETs), including heterostructure insulated gate field effect transistors (HIGFETs). At present, epitaxial layers for enhancement mode (Emode) HIGFET devices are grown directly on a substrate using a metal-organic chemical vapor deposition (MOCVD) process with an Al₂₀Ga₈₀As buffer layer with low Al mole fraction.

In addition, while the current gate length of 0.85 μm (Lg=0.85 μm) enhancement mode (Emode) NFET technology has allowed for the elimination of a drain supply switch for GSM subscriber power amplifier applications, further reduction of the device gate length will require a reduction in the off-state leakage or subthreshold current of the device.

Reducing the enhancement mode HIGFET gate length down to 0.6 μm from 0.85 μm provides an increase in small and large signal gain, an increase in output power, and an improvement in power-added efficiency (PAE).

U.S. Pat. No. 5,895,929 entitled “Low Subthreshold Leakage Current HFET,” discloses the use of thin, low temperature (LT) Al₇₅GaAs layers as arscenic (As) diffusion layers and low temperature (LT) GaAs layers within a buffer structure to reduce leakage currents for p-type heterojunction field effect transistors (HFETs) in digital applications. However, the use of a low temperature (LT) III-V material for NFETs in RF power amplifier applications degrades the RF performance characteristics of the NFETs.

U.S. Pat. No. 5,937,285 entitled “Method of Fabricating Submicron FETs with Low Temperature Group III-V Material” also discloses the use of thin LT Al₇₅GaAs and LT GaAs layers within a buffer structure to reduce leakage currents for p-type HFETS. While LT GaAs and AlGaAs in the buffer structure for NFETs and PFETs have been used for digital applications, they negatively impact the performance of large periphery NFETs (36 mm ) used in RF power amplifier applications. That is, the negative impact on performance of large periphery NFETs includes reduced drain currents and dispersive characteristics, such as, poor pulsed IV performance.

In an article by Abrokwah, J. K., Bernhardt B., LaMacchia M., entitled “Complementary GaAs (CGaAs): New Enhancements”, Solid-State Electronics Vol. 41, No. 10, pp. 1433-1439, the authors discuss use of low temperature (LT) buffer layers, optimization of rapid thermal anneal (RTA) temperature and implant schedules to reduce subthreshold leakage in PFETs for digital applications. But the NFET leakage currents reported for short gate lengths are not adequately low enough to eliminate the drain supply switch for power amplifier applications.

U.S. Pat. 6,429,103 entitled “MOCVD-Grown Emode HIGFET Buffer” discloses a form of the Emode device. That is, the ‘103 patent discloses an MOCVD-grown buffer that provides an adequate unintentionally p-type doped buffer. While the p-type doped buffer provides acceptable subthreshold leakage for the Lg=0.85 μm NFET, the same is not true for shorter gate lengths (e.g., for gate lengths Lg=0.6 μm or shorter). In other words, the unintentional p-type doping is not high enough or repeatable enough to reduce the leakage current for shorter gate lengths.

Accordingly, there is a need for an improved method and apparatus for overcoming the problems in the art as discussed above.

### BRIEF DESCRIPTION OF THE DRAWINGS

The present invention is illustrated by way of example and not limited by the accompanying figures, in which:

FIG. 1 is a cross-sectional view of a stack of layers of compound semiconductor material making up an active Emode device on a buffer layer formed using high III/V ratio material according to one embodiment of the present disclosure; and

FIG. 2 is a heterojunction field effect transistor formed in the layer stack of FIG. 1 according to an embodiment of the present disclosure.

The use of the same reference symbols in different drawings indicates similar or identical items. Skilled artisans will also appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

According to one embodiment of the present disclosure, a method for manufacturing near-theoretical subthreshold slope characteristics for a submicron NFET with gate length of approximately 0.6 μm is disclosed. In addition, a device structure comprises suitable Emode HIGFET layers grown on top of 2000 Å of GaAs, on top of a high V/III ratio and high Al mole fraction AlGaAs (75%) layer, the AlGaAs layer being approximately 2500 Å thick, on top of 1000 Å of GaAs grown on top of a GaAs substrate. Growth of the high Al mole fraction material is performed at a suitable growth temperature with a high V/III ratio (at 2× nominal or higher) utilizing a tri-methyl gallium (TMG) Ga source (as opposed to a tri-ethyl gallium (TEG) Ga source) and is key to achieving a near theoretical subthreshold swing.

The prior art epi growth methods and buffer structures rely on the unintentional p-type level of the buffer layers to adequately control the subthreshold leakage of NFETs in the one micron gate length range (0.85 μm) due to the potential barrier from the p-type buffer confining electrons. The embodiments of the present disclosure, however, utilize a thick (2500 Å), high Al mole fraction AlGaAs (75%) layer grown at a suitable growth temperature with a high V/III ratio (around 2× nominal or higher) and using a tri-methyl gallium (TMG) Ga source. This results in a higher and more repeatable p-type doping level of the buffer region due to the higher levels of carbon in the TMG Ga source. This reduces the subthreshold slope of the prior art NFET from 120 mV/decade or higher to near theorectical (70 mV/decade or less) without negatively impacting the RF performance of the NFET device.

Emode technology is a flagship technology for power amplifiers applicable to GSM, WiMAX and other linear applications in the subscriber market due to the technology's superior ruggedness and efficiency performance. A current generation of Emode technology is used in GSM front end modules and WiMAX power amplifier products. Development of a reduced gate length Emode technology is a way to increase performance and reduce future product cost.

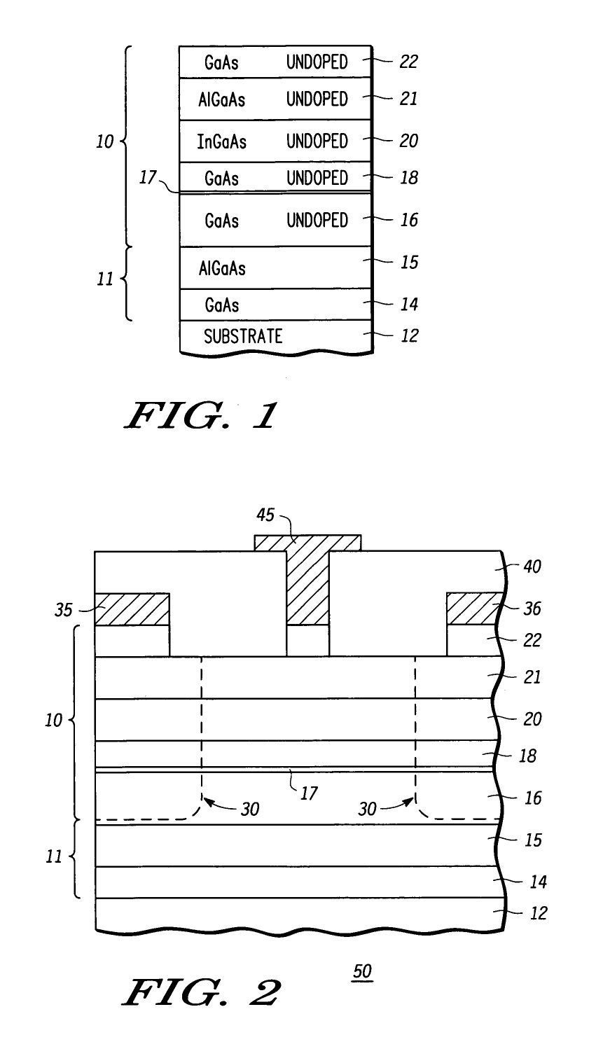

Turning now to the drawings and specifically to FIG. 1, a cross-sectional view is illustrated of a stack 10 of compound semiconductor material positioned on a buffer 11 in accordance with one embodiment of the present disclosure. A compound semiconductor substrate 12 is provided and can include, for example, a semi-insulating gallium arsenide (siGaAs) substrate. Buffer 11 includes a layer 14 of compound semiconductor material and can include, for example, a GaAs layer epitaxially grown on the upper surface of substrate 12 by a process of metal-organic chemical vapor deposition (MOCVD).

The substrate structure of FIG. 1 has been illustrated as including a supporting substrate 12 and several additional layers of material formed thereon. It should be understood that the substrate structure is utilized herein for illustrative purposes and additional or fewer layers might be included therein depending upon the application and specific material utilized. Also, while a gallium arsenide (GaAs) supporting substrate 12 is utilized and a GaAs material system is disclosed for purposes of explanation, it should be understood that other III-V material systems might be utilized for specific applications.

While the current state of the art's unintentional p-type doping level adequately provides confinement for leakage currents for a gate length Lg=0.85 μm, this is not sufficient for shorter gate lengths. A higher and more repeatable p-type doping level is required for gate lengths less than 0.85 μm (<0.85 μm ). In addition, it is imperative that the material is grown with a higher V/III ratio (i.e., on the order of 2× nominal or higher) in order to avoid an increase in dispersive characteristics.

Very high leakage current of enhancement mode devices previously grown on a substrate by the MOCVD process is due primarily to a contaminated surface of the substrate or a contaminated interface between the substrate and the epitaxial layers. A contamination of a few parts per billion is sufficient to cause leakage at the interface. It is virtually impossible to prepare a substrate without producing some contamination of the substrate surface. These contaminants at the substrate-epi interface produce mobile carriers that in turn produce the high leakage current which is detrimental to an enhancement device formed in the epitaxial layers.

To address the problem of interface contamination, layer 14 is grown at a temperature below the normal temperature for growing GaAs epitaxial layers. Typically, epitaxial layers are grown at a temperature between 550° C. and 750° C., at a generally constant growth rate. As is understood in the art, 750°0 C. is the temperature at which the growth rate of GaAs drops, given that gallium begins to evaporate at temperatures above 750° C. In the constant growth rate region, the growth of gallium arsenide is limited only by the gas phase diffusion of the material to the epi/gas interface (diffusion limited growth). In this region, atoms readily migrate into proper positions in the crystal structure so that a substantially defect free crystalline material is grown.

Below 550° C., the growth rate of GaAs decreases from the constant growth rate of the diffusion-limited region. At these lower temperatures, the epitaxial growth of GaAs is kinetically limited, i.e., some of the surface atoms may not find lattice sites and many act as interstitial or vacancy defects formed in the structure. These defects act as traps which absorb the mobile carriers at the contaminated interface. The lifetime of a free carrier in the defected GaAs is τ, which is dependent upon the number and/or distribution of the defects. In one embodiment, layer 14 containing GaAs grown with a free carrier life, τ, of less than 500 picoseconds and preferably a τ of approximately 100 picoseconds. Generally, the epitaxial growth temperature of GaAs layer 14 is between 500°0 C. and 550° C. Accordingly, GaAs layer 14 is a short-lifetime, compound semiconductor material.

The thickness of GaAs layer 14 can be varied to change the likelihood of absorption or trapping of free carriers. If the layer 14 is too thick, then the layer provides unneeded recombination far from the interface, and requires too much growth time. Accordingly, layer 14 comprises a layer of 500 Å to 1500 Å and has a carrier lifetime of less than 500 picoseconds. In one embodiment, layer 14 comprises a layer of 1000 Å with a lifetime of 100 picoseconds.

Buffer 11 also includes a layer 15 material which has a large conduction band discontinuity. Layer 15 comprises, for example, a p-type high Al mole fraction aluminum gallium arsenide (AlGaAs) layer having p-type doping concentration (Np) on the order of 2×10¹⁶ cm⁻³ to 3×10¹⁶ cm⁻³. In one embodiment, layer 15 comprises a p-type AlGaAs layer having a p-type doping concentration (Np) on the order of 2.5×10¹⁶ cm⁻³ (or 2.5e¹⁶ cm⁻³). In this embodiment, the AlGaAs is epitaxially grown with approximately fifty percent to eighty percent (50%-80%) AlAs.

Furthermore, the large conduction band discontinuity material of layer 15 comprises AlGaAs epitaxially grown with approximately seventy-five percent (75%) aluminum arsenide. In particular, a tri-methyl gallium (TMG) gallium source and a high V/III ratio (i.e., on the order of 2× nominal or higher) are used to grow a high mole fraction Al_{0.75}Ga_{0.25}As layer at a suitable growth temperature with a resulting p-type doping concentration Np in the range of 2.5e cm⁻³.

Referring still to FIG. 1, the simplified cross-sectional view illustrates stack 10 of compound semiconductor layers formed on AlGaAs layer 15 of buffer 11. In the embodiment of stack 10, a GaAs layer 16 is grown on AlGaAs layer 15 and a thin layer 17 of n-type, δdoping is deposited on layer 16 with a GaAs layer 18 epitaxially grown on the upper surface thereof. In one embodiment, the n-type dopant is silicon (Si). A layer 20 of indium gallium arsenide (InGaAs), which generally defines the device channel, is epitaxially grown on GaAs layer 18. The InGaAs in channel layer 20 is specifically selected to produce some crystallographic strain and includes high indium arsenide content to improve carrier mobility in the device channel and, thereby, reduce the device ON resistance. A layer 21 of low concentration, wide bandgap material, such as aluminum gallium arsenide (AlGaAs), is epitaxially grown on InGaAs channel layer 20 and a GaAs cap layer 22 is epitaxially grown on AlGaAs layer 21.

In one embodiment, GaAs layer 14 has a thickness on the order of 1000 Å. Al_{0.75}Ga_{0.25}As layer 15 has a thickness on the order of 2500 Å. GaAs layer 16 (including portion 18) has a thickness on the order of 2000 Å. InGaAs layer 20 has a thickness on the order of 150 Å. Al_{0.75}Ga_{0.25}As layer 14 has a thickness on the order of 1000 Å. Lastly, GaAs layer 22 has a thickness on the order of 75 Å.

The large conduction band discontinuity material of layer 15 forms a potential barrier with respect to GaAs layers 14 and 16 to prevent any free carriers, for example, that are created near the interface or avoid traps in layer 14, from entering layer 15. This potential barrier also provides additional protection to prevent free carriers from entering or leaving an Emode device structure fabricated on buffer 11.

Turning now to FIG. 2, with substrate 12, buffer 11, and stack 10 of compound semiconductor layers formed as described, GaAs cap layer 22 is covered with gate metal and masked using any appropriate technology.

A gate contact 45 is defined using any suitable photo resist (not shown) and a combination of wet and dry etch processes may be used to define the gate metal contact 45 on the upper surface of GaAs cap layer 22. Layer 22 may or may not be removed at this point in the region between gate metal and ohmic metal contacts. FIG. 2 shows layer 22 removed. Here it will be understood by those skilled in the art that standard lithographic masking and etching techniques can be used. A suitable dielectric layer 40 is then deposited.

The gate metal is spaced from the source/drain contact areas specific distances which are derived in a well known manner to provide desired characteristics (e.g. breakdown and operating voltages, etc.) for the Emode device.

Source and drain ohmic contact implants 30 and 31 (illustrated by phantom lines) are introduced into the stack of compound semiconductor layers 10. Here it should be specifically noted that implants 30 and 31 extend at least through InGaAs channel layer 20, and preferably adjacent to AlGaAs layer 15 of buffer 11. Implants 30 and 31 are spaced apart to define there between an implant (and doping) free area in InGaAs channel layer 20 and AlGaAs layer 21 (also, GaAs layers 16 and 18 and buffer 11). In this specific embodiment, GaAs cap layer 22 is undoped and implants 30 and 31 are heavily doped (n+) regions. Metal is deposited in the source and drain contact areas to form ohmic electrical contacts 35 and 36 on GaAs channel layer 22 in the source and drain contact areas.

A specific Emode device, generally designated by reference numeral 50, is illustrated and described to provide a better understanding of the embodiments of the present disclosure. However, it will be understood that other Emode devices or other embodiments of the illustrated device may be fabricated in a stack of compound semiconductor materials on buffer 11 if desired.

Accordingly, an Emode semiconductor device has been disclosed which includes a metal-organic chemical vapor deposition (MOCVD) epitaxial buffer with short-lifetime compound semiconductor material grown on a compound semiconductor substrate. The buffer includes a layer of AlGaAs. A stack of compound epitaxial layers are grown on the buffer and an enhancement mode semiconductor device is formed in the stack. The short-lifetime compound semiconductor material of the buffer absorbs or traps mobile carriers found at or near the substrate/epitaxy interface to substantially reduce leakage currents in the Emode device. Additional leakage current protection is provided by including a large conduction band discontinuity material in the buffer. Because of the particular operation of an Emode device as a normally-OFF device, leakage currents are particularly detrimental to Emode FET operation and fabrication of high quality short gate length (i.e., <0.85 μm) Emode devices by MOCVD using the previous state of the art technique results in higher and undesirable leakage currents due to low and inconsistent p-type doping levels.

Accordingly, the embodiments of the present disclosure differ from the prior known structures and methods in that the embodiments of the present disclosure utilize a TMG Ga source to grow a thick (on the order of 2500 Å high mole fraction AlGaAs layer grown at a suitable growth temperature using a higher V/III ratio to achieve a repeatable, manufacturable buffer with p-type doping in the range of 2.5e¹⁶ which exhibits excellent RF and pulsed-IV performance. An optimum growth space has been identified which simultaneously reduces the leakage current of shorter gate length NFET devices and minimizes dispersion. Furthermore, the embodiments of the present disclosure improve the performance, cost and manufacturability of Emode HIGFET device technology.

In the foregoing specification, the disclosure has been described with reference to the various embodiments. However, one of ordinary skill in the art appreciates that various modifications and changes can be made without departing from the scope of the present embodiments as set forth in the claims below. Accordingly, the specification and figures are to be regarded in an illustrative rather than a restrictive sense, and all such modifications are intended to be included within the scope of the present embodiments. The embodiments of the present disclosure can be implemented in applications such as subscriber power amplifiers, integrated circuit switches, transceiver ICs, and including, for example, GSM, WiMAX, WLAN, RFID, WCDMA or other suitable wireless radio technologies.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the term “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

1. A method of fabricating an enhancement mode semiconductor device comprising:
providing a compound semiconductor substrate;
epitaxially growing on the substrate a first portion of a buffer, the first portion including a gallium arsenide (GaAs) layer;
growing a second portion of the buffer, the second portion including (i) a high V/III ratio and (ii) high aluminum (Al) mole fraction aluminum gallium arsenide (AlGaAs);
epitaxially growing a stack of compound semiconductor layers on the buffer; and
forming an enhancement mode semiconductor device in the stack.

2. The method of claim 1, wherein growing the second portion of the buffer includes growing a high Al mole fraction material with a high V/III ratio utilizing a tri-methyl gallium (TMG) Ga source.

3. The method of claim 2, further wherein the high V/III ratio includes a V/III ratio that is at two times (2×) nominal or higher.

4. The method of claim 1, wherein the second portion of the buffer includes an aluminum gallium arsenide (AlGaAs) layer having a p-type doping (Np) on the order of 2×10¹⁶ cm⁻³ to 3×10¹⁶ cm⁻³.

5. The method of claim 4, further wherein the p-type doping (Np) is on the order of 2.5×10¹⁶ cm⁻³.

6. The method of claim 1, wherein growing the second portion of the buffer includes growing the layer of aluminum gallium arsenide with approximately seventy-five percent (75%) aluminum arsenide.

7. The method of claim 1, wherein growing the first portion of the buffer comprises growing a GaAs layer having a thickness on the order of 1000 Å.

8. The method of claim 1, wherein growing the second portion of the buffer comprises growing an Al_{0.75}Ga_{0.25}As layer having a thickness on the order of 2500 Å.

9. The method of claim 1, wherein growing the stack of compound semiconductor layers on the buffer comprise growing a GaAs layer having a thickness on the order of 2000 Å and a delta doping layer, disposed within the GaAs layer, an InGaAs layer having a thickness on the order of 150 Å, an Al_{0.75}Ga_{0.25}As layer having a thickness on the order of 1000 Å, and a GaAs layer having a thickness on the order of 75 Å.

10. A method of fabricating a substrate suitable for an enhancement mode semiconductor device comprising:
epitaxially growing a first portion of a buffer on a compound semiconductor substrate, the first portion including a gallium arsenide (GaAs) layer;
growing a second portion of the buffer, the second portion including (i) a high V/III ratio and (ii) high aluminum (Al) mole fraction aluminum gallium arsenide (AlGaAs); and
epitaxially growing a stack of compound semiconductor layers on the buffer, wherein the stack of compound semiconductor layer are suitable for forming an enhancement mode semiconductor device in the stack.

11. The method of claim 10, wherein growing the second portion of the buffer includes growing a high Al mole fraction material with a high V/III ratio utilizing a tri-methyl gallium (TMG) Ga source.

12. The method of claim 11, further wherein the high V/III ratio includes a V/III ratio that is at two times (2×) nominal or higher.

13. The method of claim 10, wherein the second portion of the buffer includes an aluminum gallium arsenide (AlGaAs) layer having a p-type doping (Np) on the order of 2×10¹⁶ cm⁻³ to 3×10¹⁶ cm⁻³.

14. The method of claim 13, further wherein the p-type doping (Np) is on the order of 2.5×10¹⁶ cm⁻³.

15. An enhancement mode semiconductor device fabricated by the method comprising:
epitaxially growing a first portion of a buffer on a compound semiconductor substrate, the first portion including a gallium arsenide (GaAs) layer;
growing a second portion of the buffer, the second portion including (i) a high V/III ratio and (ii) high aluminum (Al) mole fraction aluminum gallium arsenide (AlGaAs);
epitaxially growing a stack of compound semiconductor layers on the buffer; and
forming an enhancement mode semiconductor device in the stack.

16. The enhancement mode semiconductor device of claim 15, wherein growing the second portion of the buffer includes growing a high Al mole fraction material with a high V/III ratio utilizing a tri-methyl gallium (TMG) Ga source and wherein the high V/III ratio includes a V/III ratio that is at two times (2×) nominal or higher.

17. The enhancement mode semiconductor device of claim 15, wherein the second portion of the buffer includes an aluminum gallium arsenide (AlGaAs) layer having a p-type doping (Np) on the order of 2×10¹⁶ cm⁻³ to 3×10¹⁶ cm⁻³.

18. The enhancement mode semiconductor device of claim 15, wherein the second portion of the buffer includes a layer of aluminum gallium arsenide with approximately seventy-five percent (75%) aluminum arsenide.

19. The enhancement mode semiconductor device of claim 15, wherein the first portion of the buffer comprises a GaAs layer having a thickness on the order of 1000 Å, and the second portion of the buffer comprises an Al_{0.75}Ga_{0.25}As layer having a thickness on the order of 2500 Å.

20. The enhancement mode semiconductor device of claim 19, wherein the stack of compound semiconductor layers on the buffer comprise a GaAs layer having a thickness on the order of 2000 Å and a delta doping layer, disposed within the GaAs layer, an InGaAs layer having a thickness on the order of 150 Å, an Al_{0.75}Ga_{0.25}As layer having a thickness on the order of 1000 Å, and a GaAs layer having a thickness on the order of 75 Å.
